(19) United States
(12) Patent Application Publication
(10) Pub. No.: US 2021/0327922 A1
(43) Pub. Date: Oct. 21, 2021

(54) DISPLAY PANEL

(71) Applicant: WUHAN CHINA STAR OPTOELECTRONICS SEMICONDUCTOR DIS, Wuhan, Hubei (CN)

(72) Inventor: Qian HUANG, Wuhan, Hubei (CN)

(21) Appl. No.: 16/966,163

(22) PCT Filed: Apr. 16, 2020
(86) PCT No.: PCT/CN2020/085023

§ 371 Date: Jul. 30, 2020

(51) Int. Cl. H01L 27/12

(52) U.S. Cl. CPC H01L 27/1244; H01L 27/3258; H01L 27/1248

(57) ABSTRACT

A display panel is provided, wherein the display panel includes a base substrate, and an active layer and a bridging metal layer disposed on the base substrate and arranged at different layers. The active layer includes a plurality of active islands distributed in an array and arranged at intervals, the bridging metal layer includes a plurality of bridging traces, and two adjacent active islands are electrically connected through the bridging traces.

### FIELD OF INVENTION

The invention relates to the field of display technologies, in particular to a display panel.

### BACKGROUND OF INVENTION

In flexible bending products, stress can easily lead to damage and failure of thin film transistor (TFT) devices, affecting normal display of the products. In order to ensure a small bending radius, reducing the stress on the devices is very important during a bending process.

At present, in an array substrate of display panels, an active layer is used as a semiconductor device layer, and is simultaneously doped with phosphorus or boron element as a wire in a circuit. The active layer of traditional design has a mesh structure, and such mesh structure easily causes the active layer to break during the bending process, leading to poor display.

### Technical Problem

In the current display panels, the active layer of the traditional design has a mesh structure, and this kind of mesh structure easily causes the active layer to break during the bending process and cause a technical problem of poor display.

### SUMMARY OF INVENTION

### Technical Solution

In a first aspect, the present application provides a display panel, the display panel including a base substrate and a film-layered structure disposed on the base substrate; wherein the film-layered structure includes an active layer and a bridging metal layer arranged at different layers; and

wherein the active layer includes a plurality of active islands distributed in an array and arranged at intervals, the bridging metal layer includes a plurality of bridging traces, and two adjacent active islands are electrically connected to each other through the bridging traces.

In some embodiments, the film-layered structure further includes:

a first gate insulating layer disposed on the base substrate and covering the active layer;

a first metal layer disposed on the first gate insulating layer;

a second gate insulating layer disposed on the first gate insulating layer and the first metal layer;

a second metal layer disposed on the second gate insulating layer;

an interlayer dielectric layer disposed on the second metal layer and the second gate insulating layer; and

a source-drain metal layer disposed on the interlayer dielectric layer.

In some embodiments, the bridging traces are arranged in a same layer as the first metal layer.

In some embodiments, the bridging traces are arranged in a same layer as the second metal layer.

In some embodiments, the bridging traces are arranged in a same layer as the source-drain metal layer.

In some embodiments, the bridging traces include at least two connection lines positioned at different layers, and the connection lines in each of the bridging traces are electrically connected.

In some embodiments, the connection lines are arranged in a same layer as one of the first metal layer, the second metal layer, or the source-drain metal layer.

In some embodiments, each of the active islands includes a body and connection terminals positioned at two longitudinal sides of the body and electrically connected to the body, and the bridging traces are electrically connected to the connection terminals.

In some embodiments, the first metal layer includes a plurality of scan lines arranged in a lateral direction, and a projection of the bridging traces on the base substrate is parallel to the scan lines.

In some embodiments, a plurality of grooves are defined in the interlayer dielectric layer, an organic layer is provided in the grooves, and an orthographic projection of the grooves on the base substrate does not coincide with an orthographic projection of the active layer on the base substrate.

In some embodiments, the grooves includes a first groove and a second groove, the first groove in the interlayer dielectric layer is positioned at a region corresponding to a gap between two adjacent columns of the active islands, the second groove in the interlayer dielectric layer is positioned at a region corresponding to a gap between two adjacent rows of the active islands.

In a second aspect, the present application further provides a display panel, including a base substrate and a film-layered structure disposed on the base substrate; wherein the base substrate is a single layer or a multiple-layered structure, the film-layered structure includes an active layer and a bridging metal layer arranged at different layers; and

wherein the active layer includes a plurality of active islands distributed in an array and arranged at intervals, the bridging metal layer includes a plurality of bridging traces, and two adjacent active islands are electrically connected to each other through the bridging traces.

In some embodiments, the film-layered structure further includes:

a first gate insulating layer disposed on the base substrate and covering the active layer;

a first metal layer disposed on the first gate insulating layer;

a second gate insulating layer disposed on the first gate insulating layer and the first metal layer;

a second metal layer disposed on the second gate insulating layer;

an interlayer dielectric layer disposed on the second metal layer and the second gate insulating layer; and

a source-drain metal layer disposed on the interlayer dielectric layer.

In some embodiments, the bridging traces are arranged in a same layer as the first metal layer.

In some embodiments, the bridging traces are arranged in a same layer as the second metal layer.

In some embodiments, the bridging traces are arranged in a same layer as the source-drain metal layer.

In some embodiments, the bridging traces include at least two connection lines positioned at different layers, and the connection lines in each of the bridging traces are electrically connected.

In some embodiments, the connection lines are arranged in a same layer as one of the first metal layer, the second metal layer, or the source-drain metal layer.

In some embodiments, each of the active islands includes a body and connection terminals positioned at two longitudinal sides of the body and electrically connected to the body, and the bridging traces are electrically connected to the connection terminals.

In some embodiments, the first metal layer includes a plurality of scan lines arranged in a lateral direction, and a projection of the bridging traces on the base substrate is parallel to the scan lines.

### Beneficial Effect

Cutting a mesh-shaped active layer to form a plurality of independent active islands, and realizing electrical connection between different active traces through bridging traces of the active layer positioned at different layers at the same time, thereby achieving electrical connection between all the active islands. Meanwhile, digging grooves and filling an organic layer in a region of the interlayer dielectric layer that does not correspond to the active layer. Therefore, under the premise of ensuring that the active layer can work normally, the bending stress on the active layer during the bending process is reduced, and display failure caused by the active layer breaking during the bending process is prevented.

### BRIEF DESCRIPTION OF FIGURES

FIG. 1 is a schematic structural diagram of bridging traces arranged in a same layer as a first metal layer of a display panel according to an embodiment of the present invention.

FIG. 2 is a schematic structural diagram of bridging traces arranged in a same layer as a second metal layer of a display panel according to an embodiment of the present invention.

FIG. 3 is a schematic structural diagram of bridging traces arranged in a same layer as a source-drain metal layer of a display panel according to an embodiment of the present invention.

FIG. 4 is a schematic diagram of bridging traces including two connection lines positioned at different layers of a first structure of a display panel according to an embodiment of the present invention.

FIG. 5 is a schematic diagram of bridging traces including two connection lines positioned at different layers of a second structure of a display panel according to an embodiment of the present invention.

FIG. 6 is a schematic diagram of bridging traces including two connection lines positioned at different layers of a third structure of a display panel according to an embodiment of the present invention.

FIG. 7 is a schematic diagram of bridging traces including two connection lines positioned at different layers of a fourth structure of a display panel according to an embodiment of the present invention.

FIG. 8 is a schematic view of planar structure of partial film layer of a display panel according to an embodiment of the present invention.

FIG. 9 is a schematic view of planar structure of partial film layer of a display panel in a region corresponding to a sub-pixel according to an embodiment of the present invention.

FIGS. 10-14 are schematic flowcharts of manufacturing steps of partial film layer according to an embodiment of the present invention.

### REFERENCE NUMBER

11, base substrate; 12, buffer layer; 13, active layer; 131, active island; 1311, body; 1312, connection terminal; 14, first gate insulating layer; 15, first metal layer; 151, gate; 152, scan line; 16, second gate insulating layer; 17, second metal layer; 18, interlayer dielectric layer; 181, groove; 1811, first groove; 1812, second groove; 19, source-drain metal layer; 191, source-drain; 192, data line; 193, high-potential source line; 194, reset line; 21, bridging traces; 211, first connection line; 212, second connection line; 213, third connection line; 22, organic layer; 23, planarization layer; 24, pixel definition layer; and 25, anode metal layer.

### DETAILED DESCRIPTION OF EMBODIMENTS

In order to illustrate the technical solutions of the present disclosure or the related art in a clearer manner, the drawings desired for the present disclosure or the related art will be described hereinafter briefly. It should be understood that the specific embodiments described herein are only used to explain the application, and are not used to limit the application.

The present invention is directed to the conventional display panels in which a traditionally designed active layer has a mesh structure, and this mesh structure is likely to cause the active layer to be broken during the bending process and cause the technical problem of poor display. The present invention can solve the above problem.

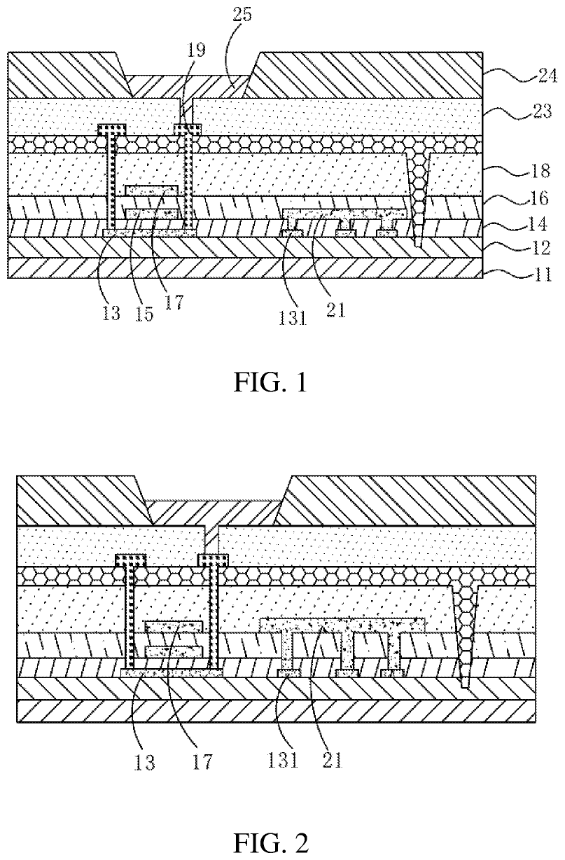

A display panel, as shown in FIG. 1, the display panel includes a base substrate 11 and a film-layered structure disposed on the base substrate 11. The film-layered structure includes an active layer 13 and a bridging metal layer arranged at different layers.

It should be noted that the display panel can be a flexible organic light-emitting diode (OLED) display panel, the base substrate 11 can be a flexible glass substrate or a flexible transparent plastic substrate, etc. The base substrate 11 can be a single-layered structure or a multiple-layered structure, such as a substrate laminated with at least two layers bonded by a transparent adhesive layer.

Specifically, the active layer 13 includes a plurality of active islands 131 distributed in an array and arranged at intervals, the bridging metal layer includes a plurality of bridging traces 21, and two adjacent active islands 131 are electrically connected to each other through the bridging traces 21.

Cut off the mesh-shaped active layer 13 to make the active islands 131 independent of each other, and realizing electrical connection between the adjacent active islands 131 through the bridging traces 21 of the active layer 13 positioned at different layers at the same time, thereby achieving electrical connection between all the active islands 131. Therefore, under the premise of ensuring that the active layer 13 can work normally, the bending stress on the active layer 13 during a bending process is reduced, and display failure caused by the active layer 13 breaking during the bending process is prevented.

It should be noted that the display panel further includes a plurality of sub-pixels distributed in an array, and the active islands 131 correspond to the sub-pixels one-to-one.

Specifically, the film-layered structure further includes a first gate insulating layer 14 disposed on the base substrate 11 and covering the active layer 13, a first metal layer 15 disposed on the first gate insulating layer 14, a second gate insulating layer 16 disposed on the first gate insulating layer 14 and the first metal layer 15, a second metal layer 17 disposed on the second gate insulating layer 16, an interlayer dielectric layer 18 disposed on the second metal layer 17 and the second gate insulating layer 16, and a source-drain metal layer 19 disposed on the interlayer dielectric layer 18.

Specifically, the display panel further includes a planarization layer 23 disposed on the interlayer dielectric layer 18, a pixel definition layer 24 and an anode metal layer 25 disposed on the planarization layer 23, and the planarization layer 23 covering the source-drain metal layer 19.

In an embodiment, a buffer layer 12 can be further provided between the base substrate 11 and the active layer 13, the active layer 13 can be disposed on the buffer layer 12, and the buffer layer 12 can be a single-layered structure or a multiple-layered structure.

In an embodiment, the bridging metal layer has a single-layered structure, that is, all the bridging traces 21 are positioned in a same film layer.

As shown in FIG. 1, the bridging traces 21 can be arranged in a same layer as the first metal layer 15, and the bridging traces 21 can be formed in a same process as the first metal layer 15 to reduce processes and save production costs.

As shown in FIG. 2, the bridging traces 21 can be arranged in a same layer as the second metal layer 17, and the bridging traces 21 can be formed in a same process as the second metal layer 17.

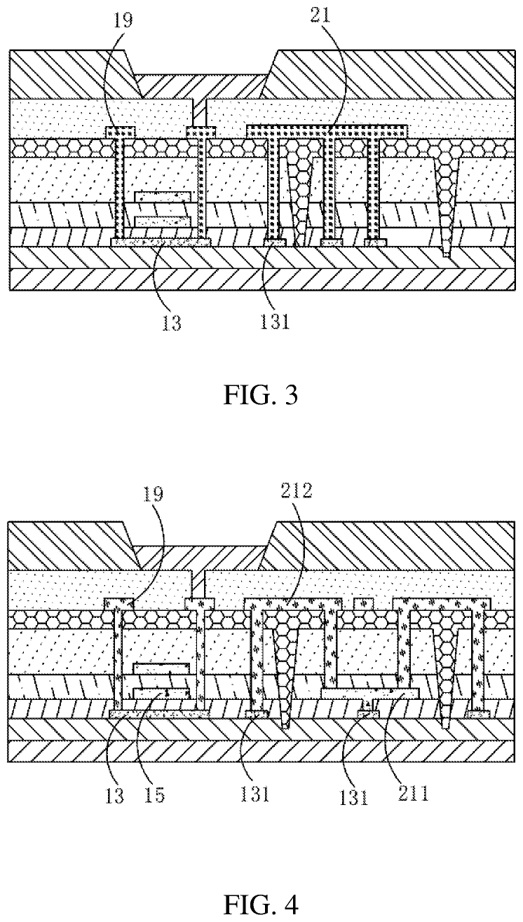

As shown in FIG. 3, the bridging traces 21 can be arranged in a same layer as the source-drain metal layer 19, and the bridging traces 21 can be formed in a same process as the second metal layer 17.

In another embodiment, as shown in FIG. 4, the bridging traces 21 include at least two connection lines positioned at different layers, and the connection lines in each of the bridging traces 21 are electrically connected.

The electrical connection between adjacent active islands 131 is achieved by providing at least two connection lines positioned at different layers, and under the premise of ensuring that the active layer 13 can work normally, the bridging traces 21 can be prevented from adversely affecting other metal trace on the display panel.

It should be noted that, the bridging traces 21 include two connection lines as an example, and the two connection lines are respectively positioned at different layers. The bridging traces 21 include at least three connection lines as an example, all the connection lines can be positioned at different film layers, alternatively, one connection line can be positioned at one film layer, and remaining connection lines can be positioned at another film layer or positioned at a plurality of film layers, respectively.

Specifically, the connection line is arranged in a same layer as one of the first metal layer 15, the second metal layer 17, or the source-drain metal layer 19.

It should be noted that, on the premise that at least two connection lines are positioned at different layers, taking the bridging traces 21 including two connection lines as an example, the two connection lines are respectively connected to any two of the first metal layer 15, the second the metal layer 17, and the source-drain metal layer 19, and are arranged in the same layer. Taking the bridging traces 21 including at least three connection lines as an example, the connection lines of the same layer as the first metal layer 15, the second metal layer 17, and the source-drain metal layer 19 can be provided at the same time. It is also possible to provide only the connection lines in the same layer as any two of the first metal layer 15, the second metal layer 17, and the source-drain metal layer 19.

As shown in FIG. 4 to FIG. 7, taking the bridging traces 21 including two connection lines positioned at different layers as an example, the connection lines include a first connection line 211 and a second connection line 212 at different layers.

In an embodiment, referring to FIG. 4, the first connection line 211 can be arranged in a same layer as the first metal layer 15, the second connection line 212 can be arranged in a same layer as the source-drain metal layer 19, the second connection line 212 is electrically connected to the first connection line 211 through a via hole, thereby electrically connecting two adjacent active islands 131.

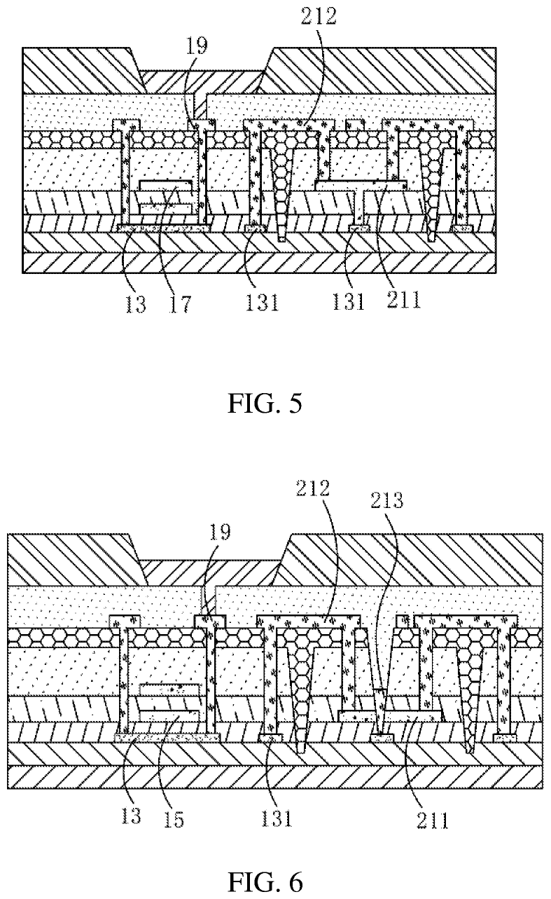

Referring to FIG. 5, the first connection line 211 can also be arranged in a same layer as the second metal layer 17, the second connection line 212 can be arranged in a same layer as the source-drain metal layer 19, the second connection line 212 is connected to the first connection line 211 through a via hole, thereby electrically connecting two adjacent active islands 131.

It should be noted that FIGS. 4 to 7 only illustrate the case where the second connection line 212 and the source-drain metal layer 19 are arranged in a same layer. In actual implementation, on the premise that the first connection line 211 and the second connection line 212 are positioned at different layers, the second connection line 212 can also be arranged in a same layer as the first metal layer 15 or the second metal layer 17.

Specifically, the connection line arranged in a same layer as the first metal layer 15 can be formed in a same process as the first metal layer 15, and the connection line arranged in a same layer as the second metal layer 17 can be formed in a same process as the second metal layer 17, and the connection line arranged in a same layer as the source-drain metal layer 19 can be formed by a same process as the source-drain metal layer 19.

It should be noted that the connection line arranged in the same layer as the first metal layer 15 is covered by the second gate insulating layer 16, the connection line arranged in the same layer as the second metal layer 17 is covered by the interlayer dielectric layer 18, and the connection line arranged in the same layer as the source-drain metal layer 19 is covered by the planarization layer 23.

In an embodiment, as shown in FIGS. 4 and 5, both the first connection line 211 and the second connection line 212 are electrically connected to at least one of the active islands 131 through a via hole.

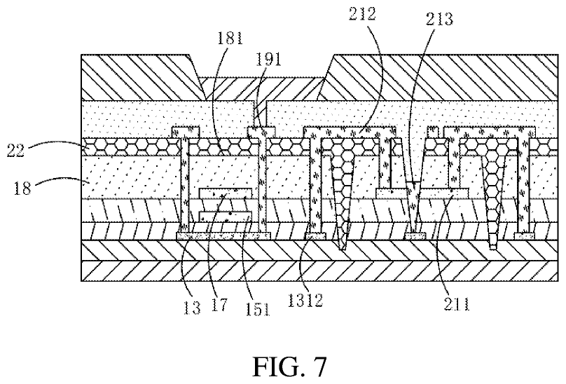

In another embodiment, as shown in FIGS. 6 and 7, the interlayer dielectric layer 18 is provided with a bridging hole that penetrates the interlayer dielectric layer 18 and extends to a surface of the active island 131. The bridging hole is filled with a conductive material to form a third connection line 213 electrically connected to the first connection line 211 and the active island 131, and the electrical connection between the first connection line 211 and the active island 131 are realized through the third connection line 213.

It should be noted that the bridging hole can penetrate the first connection line 211, and the first connection line 211 and the active island 131 can be electrically connected through the bridging hole filled with the conductive material.

It should be noted that the third connection line 213 and the second connection line 212 can be formed through a same process to reduce production costs.

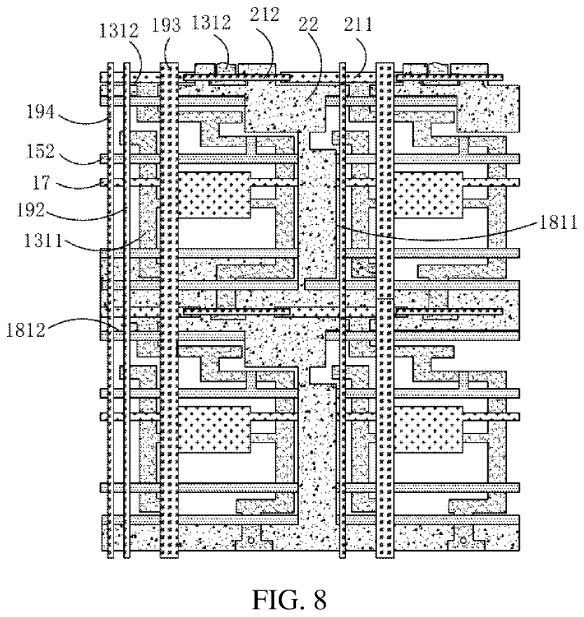

Specifically, as shown in FIGS. 7 and 8, the first metal layer 15 includes a gate 151 and a plurality of scan lines 152 arranged in a lateral direction. The source-drain metal layer 19 includes a source-drain 191, a plurality of data lines 192 arranged in a vertical direction, a high-potential source line 193, and a reset line 194. The scan lines 152 are arranged at intervals in the vertical direction, and the data lines 192 are arranged at intervals in the lateral direction.

Specifically, a plurality of grooves 181 are defined in the interlayer dielectric layer 18, an organic layer 22 is filled in the grooves 181, and an orthographic projection of the grooves 181 on the base substrate 11 does not coincide with an orthographic projection of the active layer 13 on the base substrate 11.

The grooves 181 are formed by digging grooves in a region of the interlayer dielectric layer 18 that do not correspond to the active layer 13 to reduce a thickness of the interlayer dielectric layer 18 in the region that does not correspond to the active layer 13. Moreover, the grooves 181 are filled with a flexible organic material to form the organic layer 22, the organic layer 22 can relieve the stress during bending and ensure bending performance of the display panel.

Furthermore, the grooves 181 include a first groove 1811 and a second groove 1812. The first groove 1811 in the interlayer dielectric layer 18 is positioned at a region corresponding to a gap between two adjacent columns of the active islands 131, and the second groove 1812 in the interlayer dielectric layer 18 is positioned at a region corresponding to a gap between two adjacent rows of the active islands 131.

It should be noted that the first groove 1811 and the second groove 1812 intersect and connected to each other, thereby ensuring bending performance of the region between the active islands 131.

It should be noted that a depth of the grooves 181 can be less than a thickness of the interlayer dielectric layer 18, and the grooves 181 can also penetrate the interlayer dielectric layer 18 and extend to a surface of the base substrate 11.

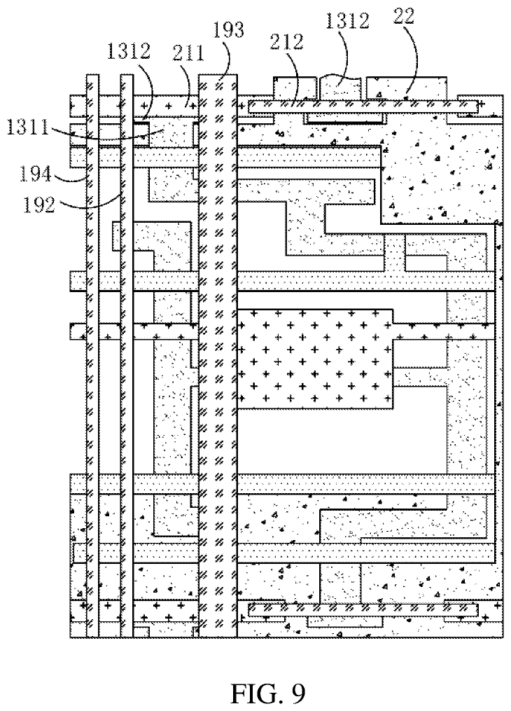

As shown in FIGS. 8 and 9, each of the active islands 131 includes a body 1311 and connection terminals 1312 positioned at two longitudinal sides of the body 1311 and electrically connected to the body 1311, and the bridging traces 21 are electrically connected to the connection terminals 1312.

It should be noted that the connection terminals 1312 can be integrally formed with the body 1311. By connecting the bridging traces 21 and the connection terminals 1312, electrical connection between adjacent active islands 131 is achieved, and the connection terminals 1312 are positioned at two longitudinal sides of the body 1311, which facilities an arrangement of the bridging traces 21 and a connection of the active islands 131.

It is noted that only an active island 131 is illustrated in FIGS. 8 and 9 as including two connection terminals 1312, and the two connection terminals 1312 are positioned at the longitudinal sides of the body 1311, respectively. In actual implementation, on the premise that the two longitudinal sides of the body 1311 are provided with connection terminals 1312, one active island 131 can further include three or more connection terminals 1312.

Specifically, a projection of the bridging traces 21 on the base substrate 11 is parallel to the scan lines 152.

Wherein, the bridging traces 21 are positioned between two adjacent bodies 1311 arranged in the longitudinal direction.

It should be noted that in a row of active islands 131, there is a gap region between two adjacent bodies 1311. By placing the connection terminals 1312 and the bridging traces 21 at the gap region, while arranging the bridging traces 21 along the lateral direction, an arrangement of the bridging traces 21 is facilitated, preventing the bridging traces 21 from adversely affecting other signal traces.

It should be noted that when the bridging traces 21 are a single-layered film layer, the bridging traces 21 are arranged in the longitudinal direction; when the bridging traces 21 include a plurality of connection lines positioned at different layers, each connection line is arranged in the lateral direction, and all the connection lines are positioned in the gap region between two adjacent bodies 1311 arranged in the longitudinal direction.

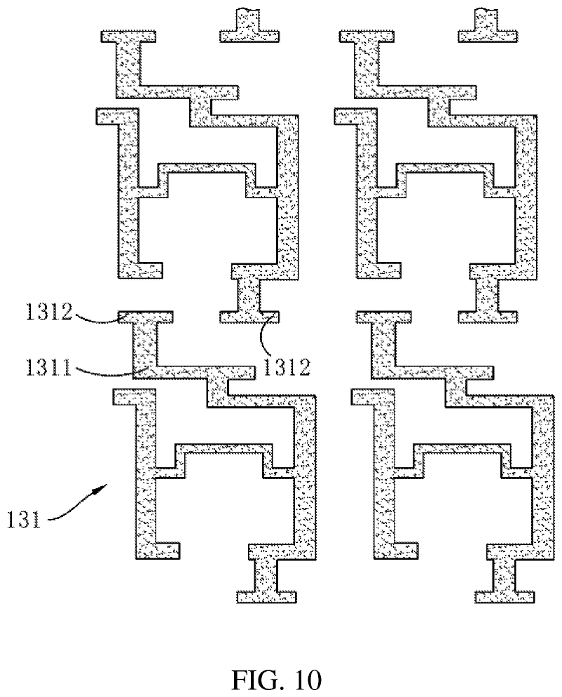

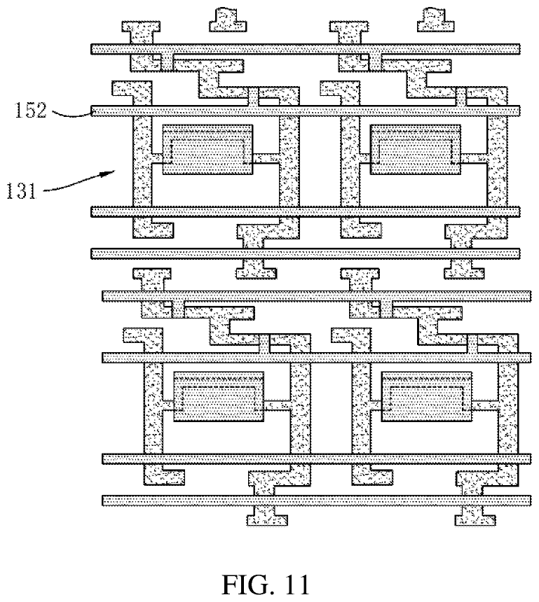

Referring to FIGS. 10 to 14, FIGS. 10 to 14 are schematic flowcharts of manufacturing steps of partial film layer on the base substrate 11 according to an embodiment of the present invention.

As shown in FIG. 10, after the active layer 13 is formed, the active layer 13 is patterned to form mesh-shaped active islands 131, the active islands 131 are separated from each other, and each of the formed active islands 131 includes a body 1311 and two connection terminals 1312 positioned at both sides of the body 1311 in the longitudinal direction.

As shown in FIG. 11, a first metal layer 15 is formed above the active layer 13, and the first metal layer 15 is patterned to form a first gate 151 and a scan line 152.

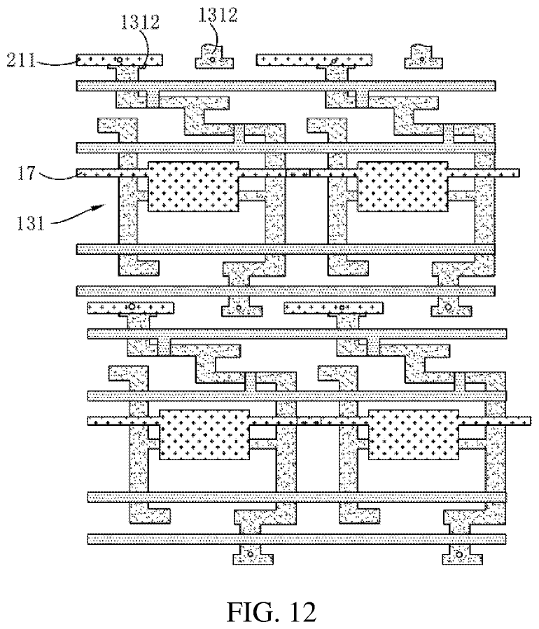

As shown in FIG. 12, a second metal layer 17 is formed above the first metal layer 15, and the second metal layer 17 is patterned to form a first connection line 211. The first connection line 211 is electrically connected to the connection terminals 1312 through via holes.

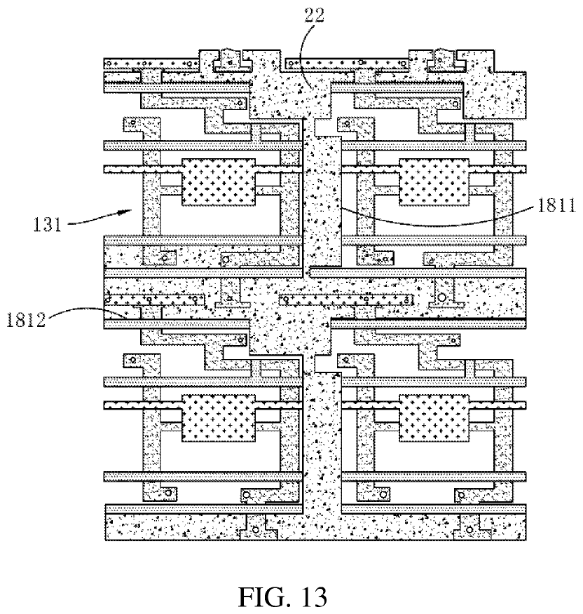

As shown in FIG. 13, after forming the interlayer dielectric layer 18 above the second metal layer 17, a plurality of grooves 181 are formed at a predetermined position on the interlayer dielectric layer 18. An orthographic projection of the grooves 181 on the base substrate 11 does not coincide with an orthographic projection of the active layer 13 on the base substrate 11. After the grooves 181 are formed, the grooves 181 are filled with an organic material to form an organic layer 22.

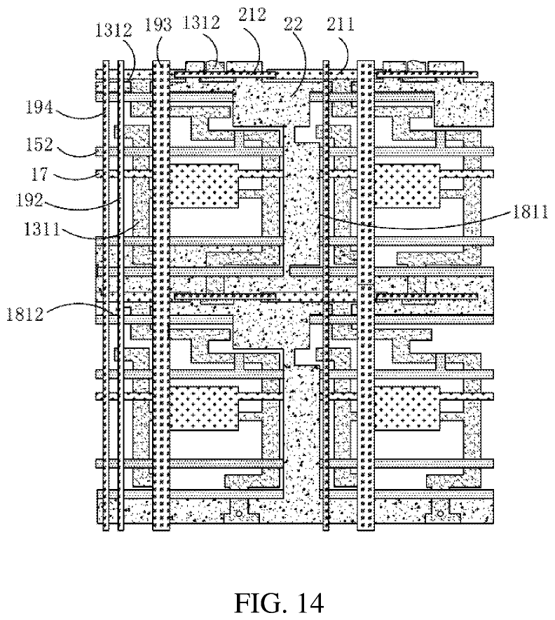

As shown in FIG. 14, a source-drain metal layer 19 is formed on the interlayer insulating layer, and the source-drain metal layer is patterned to form a source-drain 191, a data line 192, a high-potential source line 193, a reset line 194, and a second connection line 212. The second connection line 212 is electrically connected to the first connection line 211 and the connection terminals 1312 through via holes to realize electrical connection between two adjacent active islands 131.

The beneficial effects of the present invention are as follows. Cutting a mesh-shaped active layer 13 to form a plurality of independent active islands 131, and realizing electrical connection between adjacent active islands 131 through bridging traces 21 of the active layer 13 positioned at different layers at the same time, thereby achieving electrical connection between all the active islands 131. Meanwhile, digging grooves and filling an organic layer 22 in a region of the interlayer dielectric layer 18 that does not correspond to the active layer 13. Therefore, under the premise of ensuring that the active layer 13 can work normally, the bending stress on the active layer 13 during the bending process is reduced, and display failure caused by the active layer 13 breaking during the bending process is prevented.

Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A display panel, comprising a base substrate and a film-layered structure disposed on the base substrate;
wherein the film-layered structure comprises an active layer and a bridging metal layer arranged at different layers; and
wherein the active layer comprises a plurality of active islands distributed in an array and arranged at intervals, the bridging metal layer comprises a plurality of bridging traces, and two adjacent active islands are electrically connected to each other through the bridging traces.

2. The display panel according to claim 1, wherein the film-layered structure further comprises:
a first gate insulating layer disposed on the base substrate and covering the active layer;
a first metal layer disposed on the first gate insulating layer;
a second gate insulating layer disposed on the first gate insulating layer and the first metal layer;
a second metal layer disposed on the second gate insulating layer;
an interlayer dielectric layer disposed on the second metal layer and the second gate insulating layer; and
a source-drain metal layer disposed on the interlayer dielectric layer.

3. The display panel according to claim 2, wherein the bridging traces are arranged in a same layer as the first metal layer.

4. The display panel according to claim 2, wherein the bridging traces are arranged in a same layer as the second metal layer.

5. The display panel according to claim 2, wherein the bridging traces are arranged in a same layer as the source-drain metal layer.

6. The display panel according to claim 2, wherein the bridging traces comprise at least two connection lines positioned at different layers, and the connection lines in each of the bridging traces are electrically connected.

7. The display panel according to claim 6, wherein the connection lines are arranged in a same layer as one of the first metal layer, the second metal layer, or the source-drain metal layer.

8. The display panel according to claim 2, wherein each of the active islands comprises a body and connection terminals positioned at two longitudinal sides of the body and electrically connected to the body, and the bridging traces are electrically connected to the connection terminals.

9. The display panel according to claim 8, wherein the first metal layer comprises a plurality of scan lines arranged in a lateral direction, and a projection of the bridging traces on the base substrate is parallel to the scan lines.

10. The display panel according to claim 1, wherein a plurality of grooves are defined in an interlayer dielectric layer, an organic layer is provided in the grooves, and an orthographic projection of the grooves on the base substrate does not coincide with an orthographic projection of the active layer on the base substrate.

11. The display panel according to claim 10, wherein the grooves comprise a first groove and a second groove, the first groove in the interlayer dielectric layer is positioned at a region corresponding to a gap between two adjacent columns of the active islands, and the second groove in the interlayer dielectric layer is positioned at a region corresponding to a gap between two adjacent rows of the active islands.

12. A display panel, comprising a base substrate and a film-layered structure disposed on the base substrate;
wherein the base substrate is a single layer or a multiple-layered structure, the film-layered structure comprises an active layer and a bridging metal layer arranged at different layers; and
wherein the active layer comprises a plurality of active islands distributed in an array and arranged at intervals, the bridging metal layer comprises a plurality of bridging traces, and two adjacent active islands are electrically connected to each other through the bridging traces.

13. The display panel according to claim 12, wherein the film-layered structure further comprises:
a first gate insulating layer disposed on the base substrate and covering the active layer;
a first metal layer disposed on the first gate insulating layer;
a second gate insulating layer disposed on the first gate insulating layer and the first metal layer;
a second metal layer disposed on the second gate insulating layer;
an interlayer dielectric layer disposed on the second metal layer and the second gate insulating layer; and
a source-drain metal layer disposed on the interlayer dielectric layer.

14. The display panel according to claim 13, wherein the bridging traces are arranged in a same layer as the first metal layer.

15. The display panel according to claim 13, wherein the bridging traces are arranged in a same layer as the second metal layer.

16. The display panel according to claim 13, wherein the bridging traces are arranged in a same layer as the source-drain metal layer.

17. The display panel according to claim 13, wherein the bridging traces comprise at least two connection lines positioned at different layers, and the connection lines in each of the bridging traces are electrically connected.

18. The display panel according to claim 17, wherein the connection lines are arranged in a same layer as one of the first metal layer, the second metal layer, or the source-drain metal layer.

19. The display panel according to claim 13, wherein each of the active islands comprises a body and connection terminals positioned at two longitudinal sides of the body and electrically connected to the body, and the bridging traces are electrically connected to the connection terminals.

20. The display panel according to claim 19, wherein the first metal layer comprises a plurality of scan lines arranged in a lateral direction, and a projection of the bridging traces on the base substrate is parallel to the scan lines.
